(19) United States
(12) Patent Application Publication
(10) Pub. No.: US 2025/0189227 A1
(43) Pub. Date: Jun. 12, 2025

(54) SUBSTRATE PROCESSING APPARATUS AND SUBSTRATE PROCESSING METHOD

(71) Applicant: SEMES CO., LTD., Cheonan-si (KR)

(72) Inventors: Sang Min LEE, Seoul (KR); Dong Min PARK, Yongin-si (KR); Myung Chan CHO, Asan-si (KR); Ju Yeon SONG, Sokcho-si (KR)

(21) Appl. No.: 18/969,811

(22) Filed: Dec. 5, 2024

(30) Foreign Application Priority Data
Dec. 6, 2023 (KR) 10-2023-0175276

(51) Int. Cl. F26B 25/22; F26B 25/00

(52) U.S. Cl. CPC F26B 25/22; F26B 25/004

(57) ABSTRACT

Proposed is a substrate processing apparatus for processing a substrate, substrate processing apparatus including: a liquid processing chamber performing liquid processing on a substrate by supplying processing liquid to the substrate; a drying chamber drying the substrate; a transferring robot transferring the substrate from the liquid processing chamber to the drying chamber; and an inspection unit inspecting a state of the drying chamber.

### CROSS-REFERENCE TO RELATED APPLICATIONS

This application claims priority to and the benefit of Korean Patent Application No. 10-2023-0175276 filed in the Korean Intellectual Property Office on Dec. 6, 2023, the entire contents of which are incorporated herein by reference.

### TECHNICAL FIELD

The present invention relates to a substrate processing apparatus and a substrate processing method, in more detail, a substrate processing apparatus and method that dry a substrate after liquid processing.

### BACKGROUND ART

Various processes such as photographing, deposition, ashing, etching, and ion injection are performed to manufacture a semiconductor device. Further, a cleaning process of cleaning out particles remaining on a substrate is performed before and after these processes.

Meanwhile, as the etching process of these processes, a wet-type etching process that processes a substrate by discharging an etching solution and a dry-type etching process that performs plasma processing on a substrate are generally used.

In the wet-type etching process, a substrate is processed by discharging processing liquid to the substrate in a liquid processing chamber and then the substrate is transferred to a drying chamber for drying the substrate.

In this case, foreign substances such as particles or films may exist in the drying chamber before the substrate is loaded into the drying chamber. Such foreign substances are adsorbed to the surface of the substrate that is dried, or interfere with the drying process, thereby leading to a defect of processing.

### SUMMARY OF THE INVENTION

An objective of the present invention is to provide a substrate processing apparatus and a substrate processing method that prevent a defect of processing of a substrate due to a poor state of a drying chamber before the substrate liquid-processed in a liquid processing chamber is loaded into the drying chamber.

Objectives of the present invention are not limited to the objectives described above and it should be understood that other objectives not stated herein can be derived from the components described and shown in the following description and the accompanying drawings by those skilled in the art.

In order to achieve the objectives of the present invention described above, a substrate processing apparatus for processing a substrate includes: a liquid processing chamber performing liquid processing on a substrate by supplying processing liquid to the substrate; a drying chamber drying the substrate; a transferring robot transferring the substrate from the liquid processing chamber to the drying chamber; and an inspection unit inspecting a state of the drying chamber.

According to an embodiment, the inspection unit may include a camera obtaining image information by photographing an inside of the drying chamber.

According to an embodiment, the inspection unit may further include a light source unit emitting light to a photographing region of the camera in the drying chamber.

According to an embodiment, the light source unit may emit light of the band of visible light or ultraviolet rays

According to an embodiment, the state of the drying chamber may include a foreign substance state of the drying chamber.

According to an embodiment, the inspection unit may further include an image analyzer detecting whether there is the foreign substance from the image information.

According to an embodiment, the drying chamber may include: an upper body and a lower body providing a processing space therein by combining with each other; and an actuator changing positions between a state in which the processing space is closed and a state in which the processing space is open by actuating the upper body or the lower body, and the control unit may control the transferring robot to inspect the state of the drying chamber when the drying chamber is open.

According to an embodiment, a film may be provided in a partial region of at least any one of the upper body and the lower body, and the camera may inspect a state of the film.

According to an embodiment, the inspection may be performed while a substrate to be loaded into the drying chamber is processed in the liquid processing chamber.

According to an embodiment, the camera may be installed on the transferring robot.

According to an embodiment, the transferring robot may further include: a shaft; hands installed on the shaft to be movable forward and backward; and a support coupled to an upper end of the shaft, and the camera may be coupled to the shaft and the light source unit is coupled to the support.

According to an embodiment, the substrate processing apparatus may further include a control unit controlling the transferring robot, wherein the control unit may control whether to load a substrate liquid-processed in the liquid processing chamber into the drying chamber on the basis of a result of the inspection by the inspection unit.

According to an embodiment, the control unit may control the transferring robot such that the substrate is not transferred to the drying chamber when a foreign substance is detected in the drying chamber.

According to an embodiment, a substrate processing method for processing a substrate comprises performing liquid processing on a substrate by supplying processing liquid to the substrate, and loading and drying the liquid-processed substrate in a drying chamber, and inspecting a state of the drying chamber before loading the liquid-processed substrate into a drying chamber, and determining whether to load the substrate into the drying chamber on the basis of a result of the inspection.

According to an embodiment, the state of the drying chamber may include a foreign substance state of the drying chamber.

According to an embodiment, the inspection of the state of the drying chamber is performed while the liquid processing is performed.

According to an embodiment, the inspection of the drying chamber may be performed by obtaining an image by photographing the inside of the drying chamber using a camera, and by analyzing the obtained image.

According to an embodiment, the camera may be mounted on a transferring robot transferring the substrate from the liquid processing chamber to the drying chamber.

According to an embodiment, when the camera photographs the drying chamber, ultraviolet rays or visible light may be emitted to a photographing region.

Meanwhile, in order to achieve the objectives of the present invention described above, an substrate processing apparatus for processing a substrate includes: a liquid processing chamber performing liquid processing on a substrate by supplying processing liquid to the substrate; a drying chamber drying the substrate and comprising an upper body and a lower body providing a processing space therein by combining with each other and an actuator changing positions between a state in which the processing space is closed and a state in which the processing space is open by actuating the upper body or the lower body; a film provided in a partial region of at least any one of the upper body and the lower body; a transferring robot transferring the substrate from the liquid processing chamber to the drying chamber; a control unit controlling the transferring robot to inspect a state of the drying chamber when the drying chamber is open; and an inspection unit inspecting a foreign substance state of the drying chamber, wherein the inspection unit includes: a camera obtaining image information and inspecting a state of the film by photographing an inside of the drying chamber, and installed on the transferring robot; a light source unit emitting light of the band of visible light or ultraviolet rays to a photographing region of the camera in the drying chamber, and installed on the transferring robot; and an image analyzer detecting whether there is the foreign substance from the image information and performing the inspection while a substrate to be loaded into the drying chamber is processed in the liquid processing chamber.

The present invention can check the sate of the drying chamber before a substrate liquid-processed in the liquid processing chamber is loaded onto the drying chamber, so it is possible to prevent a processing defect of a substrate.

The effects of the present invention are not limited to the effects described above and those skilled in the art can understand that other effects not stated herein can be derived from the components that are used in the following specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a plan view schematically showing a substrate processing apparatus according to an embodiment of the present invention.

FIG. 2 is a view schematically showing an embodiment of the liquid processing chamber of FIG. 1.

FIG. 3 is a view schematically showing an embodiment of the drying chamber of FIG. 1.

FIG. 4 is a flowchart showing an example of a substrate processing method.

FIG. 5 is a flowchart showing an example of a substrate processing method.

FIG. 6 and FIG. 7 are views showing the flow of a transfer path of a substrate according to the order of the substrate processing method shown in FIG. 5.

FIG. 8 is a plan view of a substrate processing apparatus according to another embodiment of the present invention.

FIG. 9 is a cross-sectional view of a substrate processing apparatus according to another embodiment of the present invention.

### DETAILED DESCRIPTION

Hereinafter, embodiments of the present invention will be described in detail with reference to the accompanying drawings. Embodiments of the present invention may be modified in various ways and the scope of the present invention should not be construed as being limited to the embodiments to be described below. The embodiments are provided to more completely explain the present invention to those skilled in the art. Accordingly, the shapes of the components shown in the figures are exaggerated to enhance clearer description.

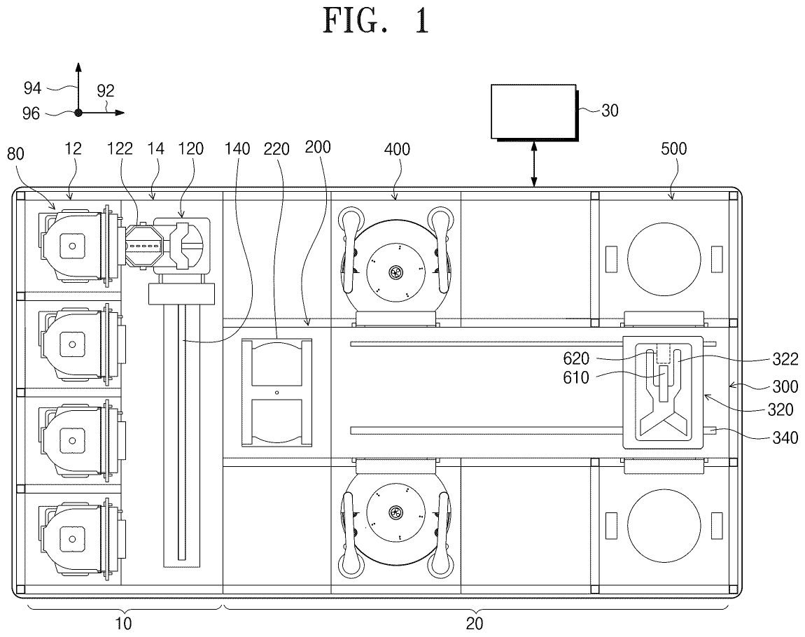

FIG. 1 is a plan view schematically showing a substrate processing apparatus according to an embodiment of the present invention.

Referring to FIG. 1, a substrate processing apparatus includes an index module 10, a processing module 20, and a control unit 30. According to an embodiment, the index module 10 and the processing module 20 are disposed in one direction. Hereafter, the direction in which the index module 10 and the processing module 20 are arranged is referred to as a first direction 92, a direction perpendicular to the first direction 92 when seen from above is referred to as a second direction 94, and a direction perpendicular to both of the first direction 92 and the second direction 94 is referred to as a third direction 96.

The index module 10 transfers substrates W to the processing module 20 from containers 80 accommodating the substrates W and puts the substrates W processed at the processing module 20 into the containers 80. The longitudinal direction of the index module 10 is provided in the second direction 94. The index module 10 has a load port 12 and an index frame 14. The load port 12 is positioned at the opposite side to the processing module 20 with the index frame 14 therebetween. The containers 80 accommodating substrates W are placed in the load port 12. A plurality of load ports 12 may be provided and the plurality of load ports 12 may be disposed in the second direction 94.

The container 80 may be a container for sealing such as a Front Open Unified Pod (FOUP). The container 80 may be placed in the load port 12 by a worker or a transferring device (not shown) such as an overhead transfer, an overhead conveyor, or an automatic guided vehicle.

An index robot 120 is provided at the index frame 14. A guide rail 140 of which the longitudinal direction is provided in the second direction 94 is provided in the index frame 14 and the index robot 120 may be provided to be movable on the guide rail 140. The index robot 120 includes a hand 122 on which substrates W are placed and the hand 122 may be provided to be able to move forward and backward, rotate about the third direction 96, and move in the third direction 96. A plurality of hands 122 may be provided to be spaced apart from each other in the up-down direction and the hands 122 can move forward and backward independently from each other.

The processing module 20 includes a buffer unit 200, a transferring chamber 300, a liquid processing chamber 400, and a drying chamber 500. The buffer unit 200 provides a space in which substrates W that are loaded into the processing module 20 and substrates W that are unloaded from the processing module 20 temporarily stay. The liquid processing chamber 400 performs a liquid processing process of performing liquid processing on substrates W by supplying liquid onto the substrates W. The drying chamber 500 can perform a processing process that removes liquid remaining on substrates W. The transferring chamber 300 transfers substrates W between the buffer unit 200, the liquid processing chamber 400, and the drying chamber 500.

The longitudinal direction of the transferring chamber 300 may be provided in the first direction 92. The buffer unit 200 may be disposed between the index module 10 and the transferring chamber 300. The liquid processing chamber 300 and the drying chamber 500 may be disposed on sides of the transferring chamber 300. The drying chamber 400 and the transferring chamber 300 may be disposed in the second direction 94. The drying chamber 500 and the transferring chamber 300 may be disposed in the second direction 94. The buffer unit 200 may be positioned at an end of the transferring chamber 300.

According to an embodiment, the liquid processing chambers 400 are disposed at both sides of the transferring chamber 300, the drying chambers 500 are disposed at both sides of the transferring chamber 300, and the liquid processing chambers 400 may be disposed at positions close to the buffer unit 200 in comparison to the drying chambers 500. The liquid processing chambers 400 may be provided in an array of A×B (A and B are each a natural number of 1 or more) in the first direction 92 and the third direction 96, respectively, at a side of the transferring chamber 300. The drying chambers 500 may be provided by the number of C×D (C and D are each a natural number of 1 or more) in the first direction 92 and the third direction 96, respectively, at a side of the transferring chamber 300. Unlike the above description, only the liquid processing chambers 400 may be provided at a side of the transferring chamber 300 and only the drying chambers 500 may be provided at another side.

The transferring chamber 300 has a transferring robot 320. A guide rail 340 of which the longitudinal direction is provided in the first direction 92 is provided in the transferring chamber 300 and the transferring robot 320 may be provided to be movable on the guide rail 340. The transferring robot 320 may include a hand 322 on which a substrate W is placed, a shaft 323 to which the hand 322 is coupled and of which the lower portion is movably connected the guide rail 340, and a support 324 that protrudes from the upper end of the shaft 323. In this case, the hand 322 may be provided to be able to rotate around the third direction 96 and move in the third direction 96. A plurality of hands 322 may be provided to be spaced apart from each other in the up-down direction and the hands 322 can move forward and backward independently from each other. A light source unit 610 to be described below may be coupled to the upper end of the support 324.

The buffer unit 200 has a plurality of buffers 220 on which substrates W are placed. The buffers 220 may be disposed to be spaced apart from each other in the third direction 96. The buffer unit 200 is open on the front face and the rear face. The front face is a surface that faces the index module 10 and the rear face is a surface that faces the transferring chamber 300. The index robot 120 can approach the buffer unit 200 through a front face and the transferring robot 320 can approach the buffer unit 200 through a rear face.

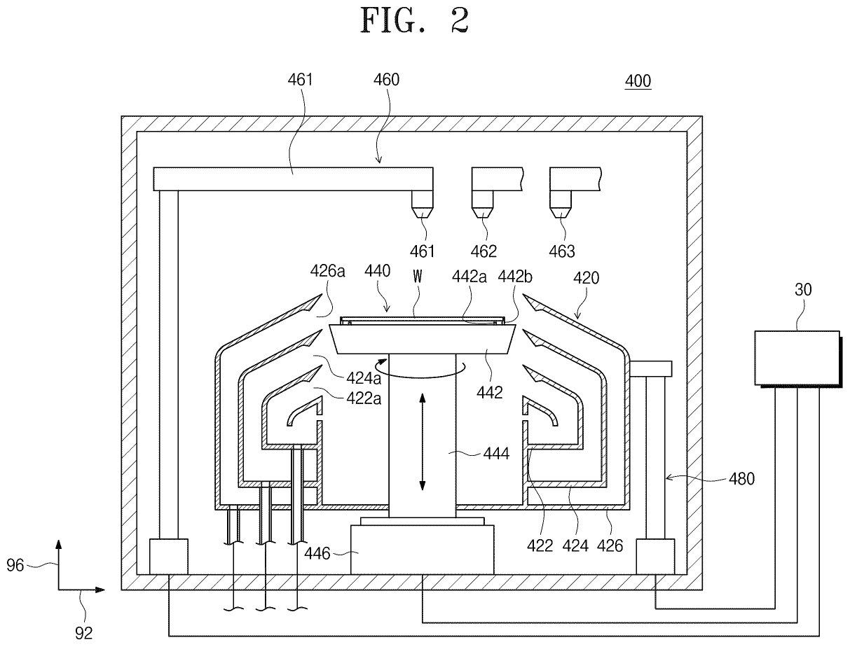

FIG. 2 is a view schematically showing an embodiment of the liquid processing chamber 400 of FIG. 1. Referring to FIG. 2, the liquid processing chamber 400 includes a housing 410, a cup 420, a supporting unit 440, a liquid supply unit 460, and an elevation unit 480. The housing 410 is provided substantially in a rectangular prism shape. The cup 420, the supporting unit 440, and the liquid supply unit 460 are disposed in the housing 410.

The cup 420 has a processing space with an open top and substrates W are liquid-processed in the processing space. The supporting unit 440 supports substrates W in the processing space. The liquid supply unit 460 supplies liquid to a substrate W supported on the supporting unit 440. A plurality of kinds of processing liquids is provided and may be sequentially supplied to a substrate W. The elevation unit 480 adjusts the relative height between the cup 420 and the supporting unit 440.

According to an example, the cup 420 has a plurality of recovery baths 422, 424, and 426. The recovery baths 422, 424, and 426 each have a recovery space for recovering liquid used to process a substrate. The recovery baths 422, 424, and 426 are each provided in a ring shape surrounding the supporting unit 440. The processing liquids splashed by rotation of a substrate W when the liquid processing process is performed flow into the recovery spaces through inlets 422a, 424a, and 426a of the recovery baths 422, 424, and 426, respectively. According to an example, the cup 420 has a first recovery bath 422, a second recovery bath 424, and a third recovery bath 426. The first recovery bath 422 is disposed to surround the supporting unit 440, the second recovery bath 424 is disposed to surround the first recovery bath 422, and the third recovery bath 426 is disposed to surround the second recovery bath 424. The second inlet 424a for supplying liquid into the second recovery bath 424 may be positioned higher than the first inlet 422a for supplying liquid into the first recovery bath 422, and the third inlet 426a for supplying liquid into the third recovery bath 426 may be positioned higher than the second inlet 424a.

The supporting unit 440 has a supporting plate 442 and an actuating shaft 444. The upper surface of the supporting plate 442 is provided substantially in a circular shape and may have a diameter larger than substrates W. Supporting pins 442a supporting the rear surface of a substrate W is provided at the center portion of the supporting plate 442 and are provided such that the upper ends thereof protrude from the supporting plate 442 to space a substrate W a predetermined distance from the supporting plate 442. Chuck pins 442b are provided on the edge portion of the supporting plate 442. The chuck pins 442b protrude upward from the supporting plate 442 and support the side of a substrate W to prevent the substrate W from separating from the supporting unit 440 when the substrate W is rotated. The actuating shaft 444 is driven by an actuator 446, is connected with the center of the underside of a substrate W, and rotates the supporting plate 442 about the center axis thereof.

According to an embodiment, the liquid supply unit 460 has a first nozzle 461, a second nozzle 462, and a third nozzle 463. The first nozzle 461 supplies processing liquid to substrates W. The processing liquid may be liquid that removes a film or foreign substances remaining on a substrate W. The second nozzle 462 supplies cleaning liquid to substrates W. The cleaning liquid may be liquid that is dissolve well in drying fluid. For example, the cleaning liquid may be liquid that is dissolve in drying fluid better than the processing liquid. The cleaning liquid may be liquid that neutralizes processing liquid supplied to a substrate W. Further, the cleaning liquid may be liquid that neutralizes processing liquid and is dissolve in drying fluid better than the processing liquid. According to an example, the cleaning liquid may be deionized water. The third nozzle 463 provides drying fluid to substrates W. The drying fluid may be liquid that is dissolved well in supercritical fluid that is used in the drying chamber 500. For example, the drying fluid may be liquid that is dissolved in supercritical fluid that is used in the drying chamber 500 better than the cleaning liquid. According to an example, the drying fluid may be organic solvent. The organic solvent may be isopropyl alcohol. The first nozzle 461, the second nozzle 462, and the third nozzle 463 are supported by different arms 467 and the arms 467 can be independently moved. Selectively, the first nozzle 461, the second nozzle 462, and the third nozzle 463 may be mounted on the same arm and moved simultaneously.

The elevation unit 480 moves the cup 420 in the up-down direction. The relative height between the cup 420 and a substrate W is changed by up-down movement of the cup 420. Accordingly, the recovery tubs 422, 424, and 426 that recover liquids are changed, depending on the kinds of processing liquids that are supplied to substrates W, so it is possible to separately recover processing liquids. Unlike the above description, the cup 420 may be fixed and the elevation unit 480 may move the supporting unit 440 in the up-down direction.

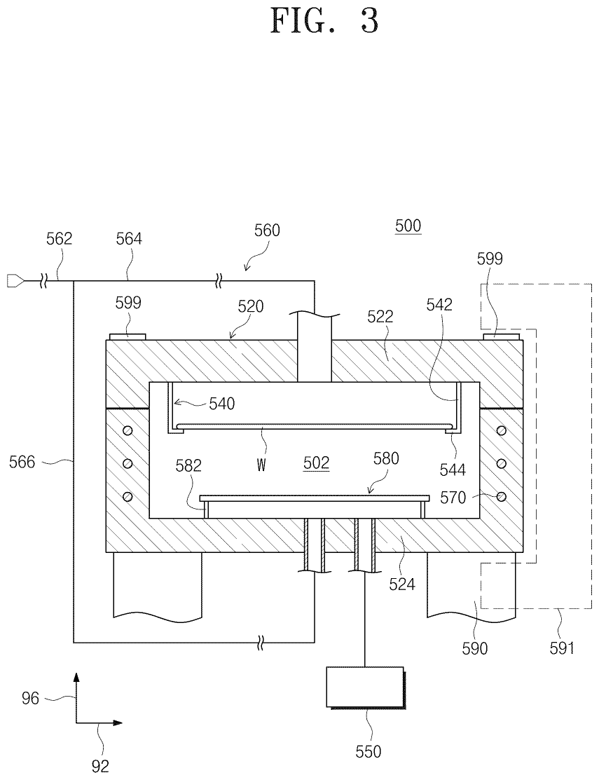

FIG. 3 is a view schematically showing an embodiment of the drying chamber of FIG. 1. According to an embodiment, the drying chamber 500 removes liquid on substrates W using supercritical fluid. The drying chamber 500 has a body 520, a supporting member 540, a fluid supply unit 560, and a blocking plate 580.

The body 520 provides a processing space 502 in which the drying process is performed. The body 520 has an upper body 522 and a lower body 524, and the upper body 522 and the lower body 524 provide the processing space 502 by combining with each other. The upper body 522 is provided over the lower body 524. The position of the upper body 522 may be fixed and the lower body 524 may be moved up and down by an actuator 590 such as a cylinder. When the lower body 524 is spaced from the upper body 522, the processing space 502 is opened and a substrate W is loaded or unloaded. When a process is performed the lower body 524 comes in close contact with the upper body 522, whereby the processing space 502 is sealed from the outside. Further, a film 599 may be provided a partial region of any one of the upper body 522 and the lower body 524 of the body 520. In this configuration, the film 599 may be configured to reduce friction of the contact region between the upper body 522 and the lower body 524 or to reduce friction on a clamper 590 that clamps the upper body 522 and the lower body 524.

The drying chamber 500 has heaters 570. According to an embodiment, the heaters 570 are positioned in the wall of the body 520. The heaters 570 heat the processing space 502 of the body 520 such that the fluid supplied into the internal space of the body 520 maintains a supercritical state.

The supporting member 540 supports a substrate W in the processing space 502 of the body 520. The supporting member 540 has a fixing rod 542 and a holder 544. The fixing rod 542 is fixedly installed on the upper body 522 to protrude downward from the underside of the upper body 522. The longitudinal direction of the fixing rod 542 is provided in the up-down direction. A plurality of fixing rods 542 is provided and the fixing rods 542 are positioned to be spaced apart from each other. The fixing rods 542 are disposed such that a substrate W does not interfere with the fixing rods 542 when the substrate W is loaded into or unloaded out of a space surrounded by the fixing rods 542. The holder 542 is coupled to the fixing rods 544. The holder 544 extends toward the space surrounded by the fixing rods 542 from the lower ends of the fixing rods 542. By the structure described above, the edge region of a substrate W loaded into the processing space 502 of the body 520 is placed on the holder 544, and the entire region of the top of the substrate W, the center region of the underside of the substrate W, and a portion of the edge region of the underside of the substrate W are exposed to processing liquid supplied into the processing space 502.

The fluid supply unit 560 supplies processing fluid into the processing space 502 of the body 520. According to an embodiment, as processing fluid, carbon dioxide in a supercritical state can be supplied into the processing space 502. Unlike, the processing fluid may be supplied into the processing space 502 in a gas state and the phase thereof may be changed into a supercritical state in the processing space 502. According to an example, the fluid supply unit 560 has a main supply line 562, an upper diverging line 564, and a lower diverging line 566. The upper diverging line 564 and the lower diverging line 566 diverge from the main supply line 562. The upper diverging line 564 is coupled to the upper body 522 and supplies processing fluid over a substrate W placed on the supporting member 540. According to an embodiment, the upper diverging line 564 is coupled to the center of the upper body 522. The lower diverging line 566 is coupled to the lower body 524 and supplies processing fluid under a substrate W placed on the supporting member 540. According to an embodiment, the lower diverging line 566 is coupled to the center of the lower body 524. An exhaust line of a fluid exhaust unit 550 is coupled to the lower body 524. The supercritical fluid in the processing space 502 of the body 520 is exhausted to the outside of the body 520 through the exhaust line of the fluid exhaust unit 550.

A blocking plate 580 may be disposed in the processing space 502 of the body 520. The blocking plate 580 may be provided in a disc shape. The blocking plate 580 is supported by a support 582 to be spaced upward apart from the bottom of the body 520. A plurality of supports 582 is provided in a rod shape and the supports 582 are spaced a predetermined distance apart from each other. When seen from above, the blocking plate 580 may be provided to overlap an outlet of the lower diverging line 566 and an inlet of the exhaust line of the fluid exhaust unit 550. The blocking plate 580 can prevent processing fluid supplied through the lower diverging line 566 from being directly discharged toward a substrate W and damaging the substrate W.

The control unit 30 controls the transferring robot 320, the liquid processing chamber 400, and the drying chamber 500 so that substrates W are processed in accordance with the substrate processing method.

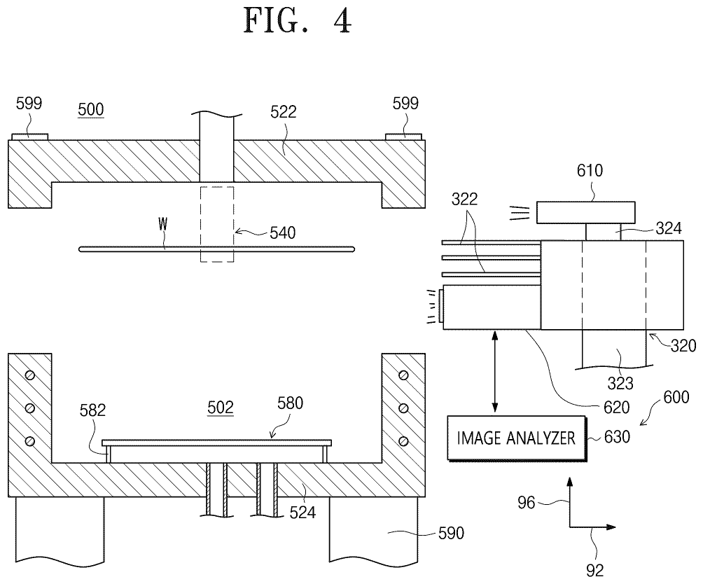

FIG. 4 is a partial cross-sectional view of a state in which an inspection unit performs inspection with the drying chamber open.

As shown in FIG. 4, the substrate processing apparatus according to an embodiment of the present invention may further include an inspection unit 600.

The inspection unit 600 is installed in the drying chamber 500 or the transferring chamber 300 and can inspect the state in the drying chamber 500. For example, the inspection unit 600 can inspect whether foreign substances remain in the drying chamber 500.

According to an embodiment, the inspection unit 600 may include a light source unit 610, a camera 620, and an image analyzer 630.

The light source unit 610 can emit light into the drying chamber 500. The light source unit 610 can emit light using an LED light source. The light that is emitted from the light source unit 610 may be light having a wavelength band that makes it possible to easily detect reflected light when the light travels to foreign substances and is reflected. According to an embodiment, the light that is emitted from the light source unit 610 may be light of the band of visible light or ultraviolet rays. In this case, the light source unit 610 can emit light toward the drying chamber 500 in the direction in which a substrate W is loaded. Accordingly, the light that is emitted from the light source unit 610 can be emitted to foreign substances existing in the path in which a substrate W is loaded and unloaded. Further, the light source unit 610 may be installed on the transferring robot 320. According to an embodiment, the light source unit 610 is coupled to the upper portion of the shaft of the transferring robot 320 and can be moved with the transferring robot 320.

The camera 620 can obtain image information by photographing the inside of the drying chamber 500. The camera 620 can obtain image in the direction in which a substrate W is loaded toward the drying chamber 500. Accordingly, the camera 620 can secure image information of foreign substance in the loading path of a substrate W. Further, the camera 620 is coupled to the lower portion of the shaft of the transferring robot 320 and can be moved with the transferring robot 320.

The image analyzer 640 can detect whether there are foreign substances by performing vision inspection on image information. In this case, foreign substances may be objects that are unexpectedly inserted in the drying chamber 500. For example, as described above, the film 599 coupled to the body 520 may be a foreign substance, and in this case, the film 599 can be separated from the body and inserted into the drying chamber 500. Further, inorganic or organic particles may be foreign substances. Further, debris from a damage substrate or fragments of components may be foreign substances. The image analyzer 630 may store in advance a reference image by photographing the inside of the drying chamber 500 without foreign substance existing in the drying chamber 500 and may detect whether foreign substances exist by comparing the reference image and obtained image information. In this case, the image analyzer 630 may have a deep learning model that is trained using image information obtained by photographing the inside of the drying chamber 500 without foreign substance existing in the drying chamber 500 and can detect foreign substances in the drying chamber 500 by comparing image information learned and stored by the deep learning model and image information input from the camera 620.

Further, when light is emitted into the drying chamber 500 from the light source unit 610 and a foreign substance reflects the light, the image analyzer 630 obtains the image information of the reflected light and analyzes the reflected light of the foreign substance in the obtained image information, thereby being able to detect whether there are foreign substances. In this case, the components inside the drying chamber 500 may be made of a material having low light reflectivity. Further, the camera 620 can obtain image information by photographing the inside of the drying chamber 500 at an angle at which light reflectivity is low.

Meanwhile, when determining that a foreign substance is detected in the drying chamber 500 by analyzing image information, the image analyzer 630 can generate and transmit a detection notification signal to the control unit 30. In this case, when receiving the detection notification signal, the control unit 30 can control the transferring robot 320 such that a substrate W is not transferred to the drying chamber 500, and can generate an alarm to a worker to perform work for removing the foreign substance.

Hereafter, a substrate processing method of the substrate processing apparatus described above is described.

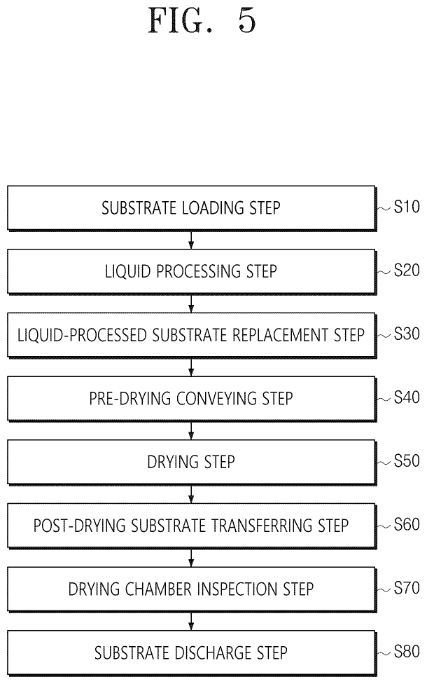

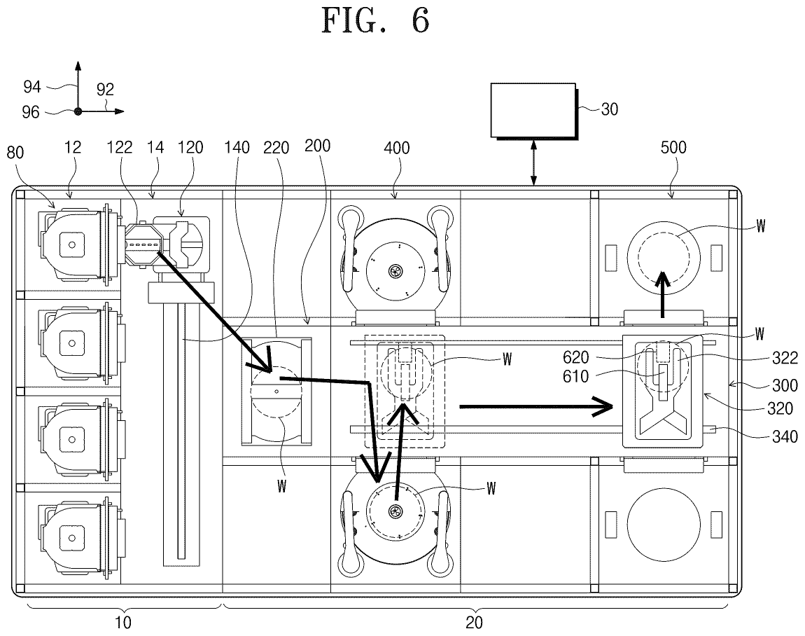

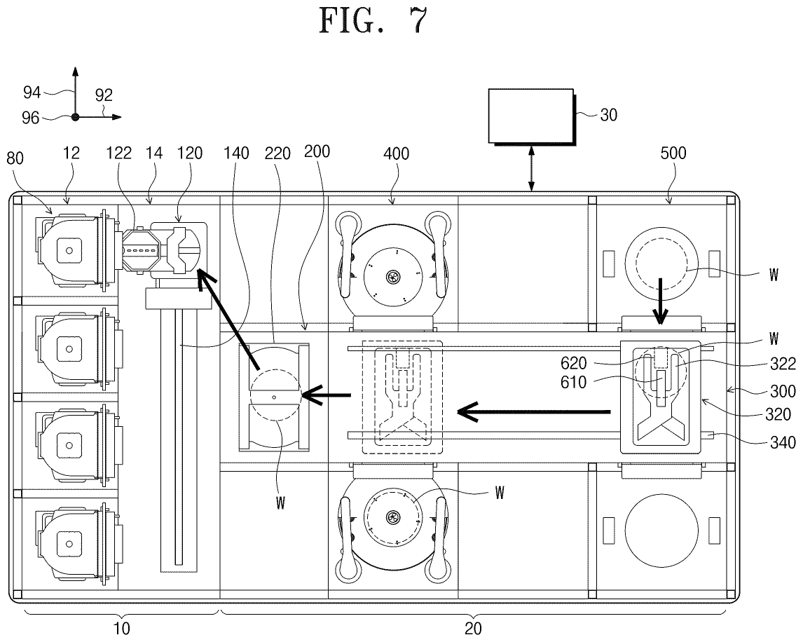

FIG. 5 is a flowchart showing an example of a substrate processing method. FIG. 6 and FIG. 7 are views showing the flow of a transfer path of a substrate according to the order of the substrate processing method shown in FIG. 5.

Referring to FIG. 5, the substrate processing method includes a substrate loading step S10, a liquid processing step S20, a liquid-processed substrate replacement step S30, a pre-drying transferring step S40, a drying step S50, a post-drying substrate transferring step S60, a drying chamber inspection step S70, and a substrate discharge step S80.

In the substrate loading step S10, as shown in FIG. 6, the index robot 120 transfers a substrate W placed in the load port 12 to the buffer 220 and the transferring robot 320 transfers the substrate W placed on the buffer 220 to the liquid processing chamber 400.

The liquid processing step S20 is performed in the liquid processing chamber 400. In the liquid processing step S20, liquid is supplied to the substrate W, thereby liquid-processing the substrate W. According to an embodiment, in the liquid processing step S20, processing liquid, cleaning liquid, and drying liquid are sequentially supplied to the substrate W, thereby processing the substrate W. The processing liquid may be chemical including an acid or a base such as sulfuric acid, nitric acid, and hydrochloric acid, the cleaning liquid may be deionized water, and the drying liquid may be isopropyl alcohol. A chemical is supplied first to the substrate W, thereby removing a thin film, foreign substance, or the like remaining on the substrate W. Thereafter, deionized water is supplied to the substrate W, thereby replacing the chemical on the substrate W with the deionized water. Thereafter, isopropyl alcohol is supplied to the substrate W, thereby replacing the deionized water on the substrate W with the isopropyl alcohol. Deionized water is dissolved well in isopropyl alcohol in comparison to chemical, so it is easily replaced. Further, the surface of the substrate W can be neutralized by the deionized water. Since isopropyl alcohol is dissolved in carbon dioxide that is used in the drying chamber 500, it is easily removed by carbon dioxide that is processing fluid in a supercritical state in the drying chamber 500.

In the liquid-processed substrate replacement step S30, the substrate W that has been liquid-processed in the liquid processing chamber 400 is unloaded to the transferring robot 320, and simultaneously, another substrate W seated on the plurality of hands 322 is loaded into the liquid processing chamber 400. In this case, the liquid processing step S20 described above can be performed on the substrate W loaded into the liquid processing chamber 400.

The pre-drying transferring step S40 is performed by the transferring robot 320. When liquid processing is finished in the liquid processing chamber 400, the pre-drying transferring step S40 that transfers the substrate W from the liquid processing chamber 400 to the drying chamber 500 is performed. Liquid remains on the substrate W while the substrate W is transferred to the transferring robot 320. Hereafter, the liquid remaining on the substrate W while the substrate W is transferred to the transferring robot 320 is referred to as processing liquid. For example, the processing liquid may be drying liquid in the example described above.

The drying step S50 is performed in the drying chamber 500. The substrate S loaded into the drying chamber 500 is supported on the supporting member 540 with the edge region on the holder 544. Carbon dioxide is supplied first to the processing space 502 of the body 520 through the lower diverging line 566. When the processing space 502 of the body 520 reaches a set pressure, the carbon dioxide is supplied to the processing space 502 of the body 520 through the upper diverging line 564. Selectively, when the processing space 502 of the body 520 reaches the set pressure, the carbon dioxide may be supplied to the processing space 502 of the body 520 simultaneously through the upper diverging line 564 and the lower diverging line 566. When the process is performed, supply of carbon dioxide to the processing space 502 of the body 520 and discharge of carbon dioxide from the processing space 502 may be periodically performed multiple times. When the processing liquid remaining on the substrate W is dissolve by a predetermined amount in the carbon dioxide that is processing liquid in a supercritical state, the carbon dioxide is discharged from the processing space 502 and new carbon dioxide is supplied to the processing space 502, whereby the removal rate of processing liquid from the substrate W can be improved.

In the post-drying substrate transferring step S60, as shown in FIG. 7, the transferring robot 320 discharges the dried substrate W to the transferring chamber 300 outside the drying chamber 500.

The drying chamber inspection step S70 may be performed immediately after or simultaneously with the post-drying substrate transferring step S60. The drying chamber inspection step S70 is performed, as shown in FIG. 4, the upper body 522 and the lower body 524 spaced apart from each other and the processing space 502 open. In this case, the light source unit 610 emits light into the drying chamber 500, the camera 620 obtains image information of the drying chamber 500, and the image analyzer 630 can inspect whether there are foreign substances by comparing the obtained image information and image information stored in advance. As described above, the foreign substances may be particles or the film 599. In this case, the image analyzer 630 can detect whether foreign substances remain by analyzing the image information of light reflected by the foreign substances or can detect image information of foreign substances that are not allowed in the image of the inside of the drying chamber 500. In this case, when particles are detected in the drying chamber inspection step S70, the image analyzer 630 transmits a detection alarm signal to the control unit 30 and the control unit 30 receiving the detection alarm signal can control the transferring robot 320 such that the substrate liquid-processed in the liquid processing chamber 400 is not transferred to the drying chamber 500 and can generate an alarm to a worker to perform work for removing the foreign substances.

In the substrate discharge step S80, the transferring robot 320 can transfer the dried substrate W to the buffer 220 of the buffer unit 200 from the transferring chamber 300 and the index robot 120 can discharge the substrate W seated on the buffer 220 to the load port 12. In this case, the transferring robot 320 can receive a new substrate W, which should be liquid-processed and dried, from the buffer 220 in the process of discharging the dried substrate from the buffer 220.

Thereafter, the substrate processing method of the present invention is sequentially started again from the substrate loading step S10 described above. In this case, since the drying chamber inspection step S70 has been performed in the drying chamber 500 while a substrate is liquid-processed in the liquid processing chamber 400, the pre-drying transferring step S40 and the drying step S50 can be immediately performed on the liquid-processed substrate W. Accordingly, the substrate processing method of the present invention can prevent the processing time for a substrate from increasing in comparison to the related art even though the drying chamber inspection step S70 is additionally performed.

As described above, the substrate processing apparatus and the substrate processing method according to the present invention can prevent poor processing of a substrate W because it is possible to check whether particles remain in the drying chamber 500 in the process of loading the substrate W liquid-processed with processing liquid to the drying chamber 500 to dry the substrate W.

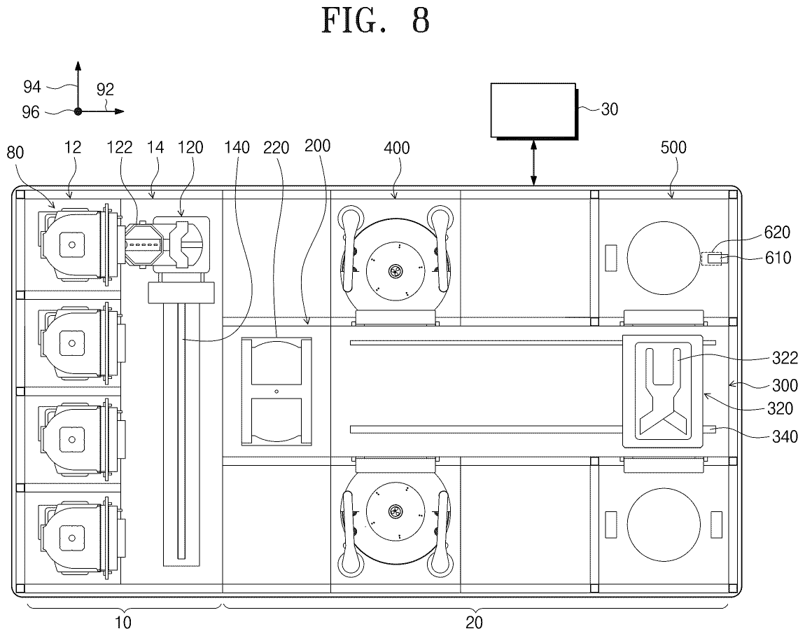

FIG. 8 is a plan view of a substrate processing apparatus according to another embodiment of the present invention.

As shown in FIG. 8, the light source unit 610 and the camera 620 according to an embodiment of the present invention may be disposed at various positions such as being positioned around the drying chamber 500 or being positioned in the drying chamber 500 rather than being coupled to the shaft of the transferring robot 320, as exemplified in the embodiment described above.

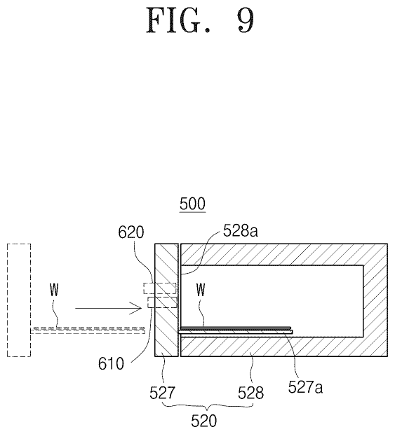

FIG. 9 is a cross-sectional view of a substrate processing apparatus according to another embodiment of the present invention.

As shown in FIG. 9, the body 520 of the drying chamber may not be divided into an upper body and a lower body, as in the embodiment described above, and may include a box 528 having an insertion hole 528a in which a substrate W is inserted on a side and a drawer 527 that is slid into the insertion hole 528a of the body 528 with a substrate W seated on a table 527a. In this case, the inspection unit 600 may be configured in a type in which the light source unit 610 and the camera 620 are combined with the drawer 527. In this way, the body of the drying chamber 500 may be changed in various shapes and the inspection unit 600 may also be coupled or disposed at various positions, depending on the shape of the drying chamber 500.

Hereinabove, although the present invention is described by specific matters such as concrete components, and the like, embodiments, and drawings, they are provided only for assisting in the entire understanding of the present invention. Therefore, the present invention is not limited to the embodiments. Various modifications and changes may be made by those skilled in the art to which the present invention pertains from this description.

Therefore, the spirit of the present invention should not be limited to the above-described embodiments, and the following claims as well as all modified equally or equivalently to the claims are intended to fall within the scope and spirit of the invention.

1. A substrate processing apparatus for processing a substrate, comprising:
a liquid processing chamber performing liquid processing on a substrate by supplying processing liquid to the substrate;
a drying chamber drying the substrate;
a transferring robot transferring the substrate from the liquid processing chamber to the drying chamber; and
an inspection unit inspecting a state of the drying chamber.

2. The substrate processing apparatus of claim 1, wherein the inspection unit comprises a camera obtaining image information by photographing an inside of the drying chamber.

3. The substrate processing apparatus of claim 2, wherein the inspection unit further comprises a light source unit emitting light to a photographing region of the camera in the drying chamber.

4. The substrate processing apparatus of claim 3, wherein the light source unit emits light of the band of visible light or ultraviolet rays.

5. The substrate processing apparatus of claim 2, wherein the state of the drying chamber comprises a foreign substance state of the drying chamber.

6. The substrate processing apparatus of claim 2, wherein the inspection unit comprises an image analyzer detecting whether there is the foreign substance from the image information.

7. The substrate processing apparatus of claim 2, wherein the drying chamber comprises:
an upper body and a lower body providing a processing space therein by combining with each other; and
an actuator changing positions between a state in which the processing space is closed and a state in which the processing space is open by actuating the upper body or the lower body, and
the control unit controls the transferring robot to inspect the state of the drying chamber when the drying chamber is open.

8. The substrate processing apparatus of claim 2, wherein a film is provided in a partial region of at least any one of the upper body and the lower body, and
the camera inspects a state of the film.

9. The substrate processing apparatus of claim 2, wherein the inspection is performed while a substrate to be loaded into the drying chamber is processed in the liquid processing chamber.

10. The substrate processing apparatus of claim 3, wherein the camera is installed on the transferring robot.

11. The substrate processing apparatus of claim 10, further comprising:
a shaft;
hands installed on the shaft to be movable forward and backward; and
a support coupled to an upper end of the shaft, and
the camera is coupled to the shaft and the light source unit is coupled to the support.

12. The substrate processing apparatus of claim 1, further comprising a control unit controlling the transferring robot,
wherein the control unit controls whether to load a substrate liquid-processed in the liquid processing chamber into the drying chamber on the basis of a result of the inspection by the inspection unit.

13. The substrate processing apparatus of claim 12, wherein the control unit controls the transferring robot such that the substrate is not transferred to the drying chamber when a foreign substance is detected in the drying chamber.

14.-19. (canceled)

20. A substrate processing apparatus for processing a substrate, comprising:
a liquid processing chamber performing liquid processing on a substrate by supplying processing liquid to the substrate;
a drying chamber drying the substrate and comprising an upper body and a lower body providing a processing space therein by combining with each other and an actuator changing positions between a state in which the processing space is closed and a state in which the processing space is open by actuating the upper body or the lower body;
a film provided in a partial region of at least any one of the upper body and the lower body;
a transferring robot transferring the substrate from the liquid processing chamber to the drying chamber;
a control unit controlling the transferring robot to inspect a state of the drying chamber when the drying chamber is open; and
an inspection unit inspecting a foreign substance state of the drying chamber,
wherein the inspection unit comprises:
a camera obtaining image information and inspecting a state of the film by photographing an inside of the drying chamber, and installed on the transferring robot;
a light source unit emitting light of the band of visible light or ultraviolet rays to a photographing region of the camera in the drying chamber, and installed on the transferring robot; and
an image analyzer detecting whether there is the foreign substance from the image information and performing the inspection while a substrate to be loaded into the drying chamber is processed in the liquid processing chamber.
